(19) United States
(12) Patent Application Publication
(10) Pub. No.: US 2026/0316181 A1
(43) Pub. Date: Oct. 15, 2026

(54) LASER WELDING METHOD AND JOINED ASSEMBLY

(71) Applicants: TOYOTA JIDOSHA KABUSHIKI KAISHA, Toyota-shi (JP); Toyoda Iron Works Co., Ltd., Toyota-shi (JP)

(72) Inventors: Ryuta MATSUO, Nagakute-shi (JP); Yoshinari SHIBAYAMA, Nagoya-shi (JP)

(73) Assignees: TOYOTA JIDOSHA KABUSHIKI KAISHA, Toyota-shi (JP); Toyoda Iron Works Co., Ltd., Toyota-shi (JP)

(21) Appl. No.: 19/467,001

(22) Filed: Feb. 2, 2026

(30) Foreign Application Priority Data
Feb. 10, 2025 (JP) 2025-019764

(51) Int. Cl. B23K 26/082; B23K 26/21

(52) U.S. Cl. CPC B23K 26/082; B23K 26/21

(57) ABSTRACT

In a laser welding method according to the present disclosure, a plurality of stacked metal plates is welded together by irradiating the metal plates with a laser beam. The laser welding method includes: irradiating the metal plates with the laser beam to form a molten pool; and scanning the laser beam one or more times along the periphery of the molten pool to enlarge the molten pool. The molten pool is formed in an oval shape as viewed in plan.

### CROSS-REFERENCE TO RELATED APPLICATION

This application claims priority to Japanese Patent Application No. 2025-019764 filed on Feb. 10, 2025. The disclosure of the above-identified application, including the specification, drawings, and claims, is incorporated by reference herein in its entirety.

### BACKGROUND

### 1. Technical Field

The present disclosure relates to laser welding methods and joined assemblies.

### 2. Description of Related Art

Japanese Unexamined Patent Application Publication No. 2012-228715 (JP 2012-228715 A) discloses a method for welding a plurality of stacked metal plates by irradiating them with a laser beam while scanning the laser beam in a circular path.

### SUMMARY

The inventors investigated a laser welding method in which a plurality of stacked metal plates is welded by irradiating them with a laser beam while scanning the laser beam along a circular path, and identified the following issue.

In this laser welding method, welding is performed while maintaining a gap between the plates. As a result, the throat thickness of the welded portion is small, and there is a risk that sufficient fatigue strength may not be ensured in the welded portion formed as the molten pool solidifies.

The present disclosure has been made to address the above issue, and provides a laser welding method and a joined assembly capable of ensuring sufficient fatigue strength of a welded portion.

A laser welding method according to the present disclosure is a laser welding method in which a plurality of metal plates stacked together is welded together by irradiating the metal plates with a laser beam. The laser welding method includes: irradiating the metal plates with the laser beam to form a molten pool; and scanning the laser beam one or more times along the periphery of the molten pool to enlarge the molten pool. The molten pool is formed in an oval shape as viewed in plan.

The oval shape may be a shape in which semicircles are connected by straight line portions, and the straight line portions may be longer than the radius of the semicircles.

The straight line portions may have a length of at least 1 mm.

A joined assembly according to the present disclosure is a joined assembly in which a plurality of metal plates stacked together is welded together by irradiating the metal plates with a laser beam. A weld joining the metal plates has an oval shape as viewed in plan.

The oval shape may be a shape in which semicircles are connected by straight line portions, and the straight line portions may be longer than the radius of the semicircles.

The present disclosure provides a laser welding method and a joined assembly capable of ensuring sufficient fatigue strength of a welded portion.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram of a laser welding system according to a first embodiment;

FIG. 2 is a plan view of a molten pool according to the first embodiment;

FIG. 3 is a plan view of a molten pool in Comparative Examples; and

FIG. 4 is a graph showing the S-N curves of an Example, Comparative Example 1, and Comparative Example 2.

### DETAILED DESCRIPTION OF EMBODIMENTS

Hereinafter, a specific embodiment of the present disclosure will be described in detail with reference to the drawings. However, the present disclosure is not limited to the following embodiment. For clarity, the following description and drawings are simplified as appropriate.

### First Embodiment

### Configuration of Laser Welding System

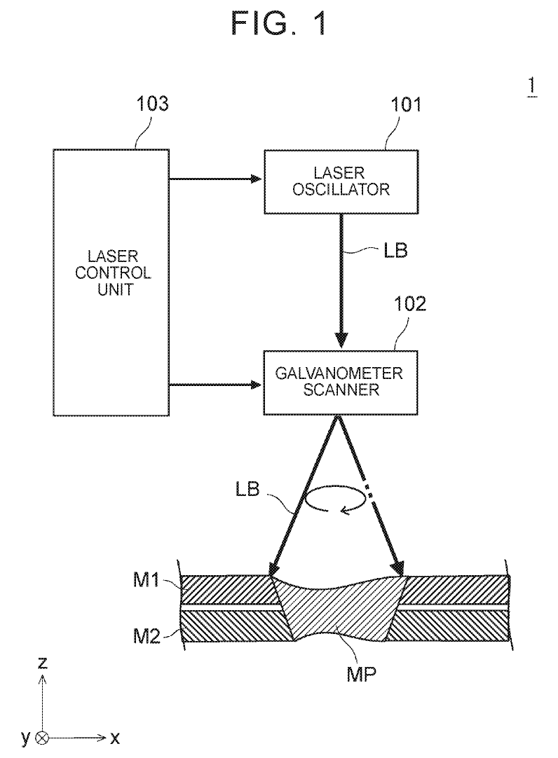

First, a laser welding system (LWS) according to a first embodiment will be described with reference to FIG. 1. FIG. 1 is a block diagram of the laser welding system according to the first embodiment. As shown in FIG. 1, a laser welding system 1 according to the present embodiment irradiates two stacked metal plates M1, M2 with a laser beam LB. As a result, a molten pool MP penetrating the two metal plates M1, M2 is formed, and the two metal plates M1, M2 are welded together to form a joined assembly. The laser welding system 1 shown in FIG. 1 may be mounted on, for example, a manipulator (robot arm).

As shown in FIG. 1, the laser welding system 1 includes a laser oscillator 101, a galvanometer scanner 102, and a laser control unit 103.

It should be understood that the right-handed xyz Cartesian coordinate system shown in FIG. 1 and other figures is provided merely for convenience in describing the positional relationships of the components. In FIG. 1 and other figures, the positive z-axis points vertically upward and the xy-plane is a horizontal plane throughout the drawings.

The metal plates M1, M2, which are the objects to be welded, are not particularly limited, and may be, for example, steel plates or aluminum alloy plates constituting a vehicle. The metal plates M1, M2 may be made of, for example, the same metal, but may alternatively be made of different metals. The number of metal plates to be welded may be three or more.

The laser oscillator 101 generates a laser beam LB with an output determined based on a control signal from the laser control unit 103. The laser beam LB output from the laser oscillator 101 is input to the galvanometer scanner 102.

The laser oscillator 101 and the galvanometer scanner 102 together constitute a laser irradiation unit that irradiates the metal plates M1, M2, which are the objects to be welded, with the laser beam LB.

The galvanometer scanner 102 irradiates the metal plates M1, M2, which are the objects to be welded, with the laser beam LB while scanning across the metal plates M1, M2 according to a control signal from the laser control unit 103. Based on control signals from the laser control unit 103, parameters such as the spot diameter, scanning speed, trajectory, and scanning start point of the laser beam LB output from the galvanometer scanner 102 are determined.

As shown in FIG. 1, the molten pool MP is formed by scanning the laser beam LB output from the galvanometer scanner 102 across the stacked metal plates M1, M2. The formed molten pool MP is enlarged by scanning the laser beam LB one or more times along the periphery of the molten pool MP.

The laser control unit 103 controls the irradiation conditions of the laser beam LB. Specifically, the laser control unit 103 controls the output (laser output) of the laser beam LB generated by the laser oscillator 101. The laser control unit 103 also controls parameters such as the spot diameter, scanning speed, and trajectory of the laser beam LB output from the galvanometer scanner 102.

Although not shown in the figures, the laser control unit 103 includes, for example, a processing unit such as a central processing unit (CPU), and a storage unit such as random access memory (RAM) or read-only memory (ROM) in which various control programs and data are stored. In other words, the laser control unit 103 functions as a computer and performs various control processes based on the control programs.

Accordingly, the laser control unit 103 shown in FIG. 1 may be configured in hardware by the CPU, the storage unit, and other circuits, and may be implemented in software by the various control programs stored in the storage unit. In other words, the laser control unit 103 may be implemented in hardware, software, or a combination thereof.

### Laser Welding Method

Next, the laser welding method according to the first embodiment will be described.

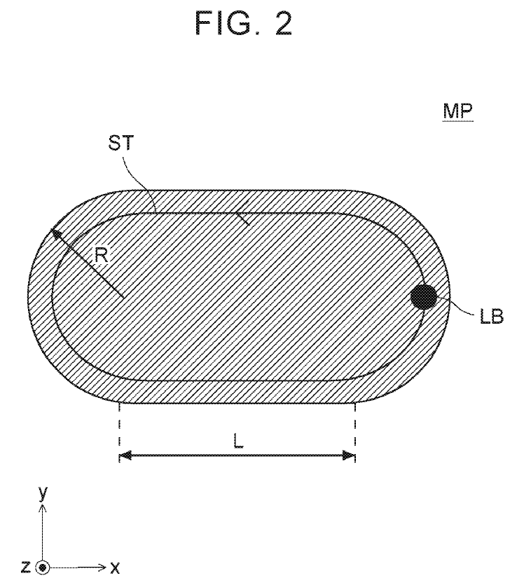

First, the molten pool MP formed by the laser welding method according to the first embodiment will be described with reference to FIG. 2. FIG. 2 is a plan view of the molten pool MP according to the first embodiment. Although FIG. 2 is a plan view, the molten pool MP is shown with multiple hatching lines for ease of understanding.

The molten pool MP according to the first embodiment is formed in an oval shape as viewed in the xy-plane. More specifically, as shown in FIG. 2, the molten pool MP is formed in a shape in which two semicircles are connected by straight line portions. In addition to the shape shown in FIG. 2, the molten pool MP may also be formed in other oval shapes such as an elliptical shape.

As shown in FIG. 2, the weld formed as the molten pool MP solidifies also has a shape in which two semicircles are connected by straight line portions. It is preferable that the molten pool MP be formed such that straight line portions L of the molten pool MP are substantially perpendicular to the load input direction. As a result, stresses applied to the weld can be suitably distributed, and the weld can ensure sufficient fatigue strength. As shown in FIG. 2, increasing the length of the straight line portions L beyond the radius R of the semicircles further improves the fatigue strength of the weld. Preferably, the straight line portions L have a length of at least 1 mm.

The laser welding method according to the first embodiment will now be described with reference to FIG. 2.

First, the two stacked metal plates M1, M2 are irradiated with the laser beam LB output from the galvanometer scanner 102. At this time, as shown in FIG. 2, the laser beam LB is scanned across the stacked metal plates M1, M2 such that, for example, the scanning trajectory ST describes an oval. As a result, the molten pool MP having an oval shape as viewed in the xy-plane is formed. In FIG. 2, the laser beam LB is scanned counterclockwise. However, the laser beam LB may be scanned clockwise. In the scanning trajectory ST of the laser beam LB, the straight line portions L are longer than the radius R of the semicircles. More preferably, the straight line portions L have a length of at least 1 mm.

Next, the molten pool MP is enlarged by scanning the laser beam LB along the periphery of the molten pool MP one or more times. As shown in FIG. 2, the enlarged molten pool MP also has an oval shape. When the molten pool MP is cooled and solidified, it becomes a weld.

As described above, in the laser welding method according to the present embodiment, the molten pool MP is formed in an oval shape as viewed in plan. Specifically, the molten pool MP is formed in a shape in which two semicircles are connected by straight line portions. This makes it possible to suitably distribute stresses applied to the weld. Accordingly, the weld that joins the metal plates, that is, the welded portion, can ensure sufficient fatigue strength.

The laser welding method according to the first embodiment will be described in further detail below with reference to an Example and Comparative Examples. However, the laser welding method according to the first embodiment is not limited to the following Example. Two types of Comparative Examples, namely Comparative Example 1 and Comparative Example 2, were used.

### Test Conditions

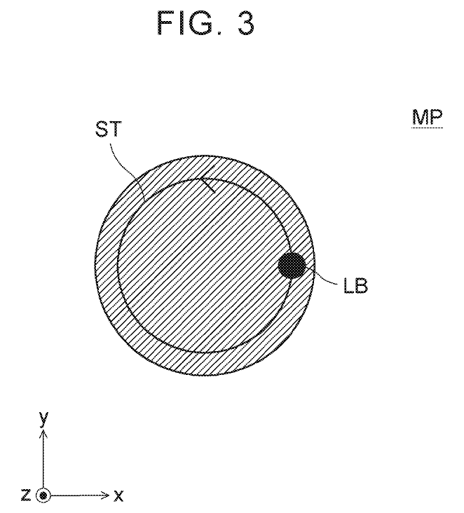

First, the test conditions will be described with reference to FIGS. 2 and 3. FIG. 3 is a plan view of a molten pool in the Comparative Examples.

The test specimens of the Example, Comparative Example 1, and Comparative Example 2 were welded specimens formed by joining a pair of L-shaped metal plates together by welding. The weld of the Example was formed in an oval shape, and more specifically, in a shape in which two semicircles are connected by straight line portions, as shown in FIG. 2. In contrast, the welds of Comparative Examples 1, 2 were formed in a circular shape, as shown in FIG. 3. In the Example and Comparative Example 1, the metal plates were welded together by irradiating them with a laser beam LB using the laser welding system 1. In Comparative Example 2, the metal plates were welded together by spot welding. In the Example and Comparative Example 1 in which laser welding was used, the L-shaped metal plates were welded together with a gap of 0.6 mm therebetween. In contrast, in Comparative Example 2 in which spot welding was used, the L-shaped metal plates were welded together without any gap therebetween, i.e., with a gap of 0 mm.

A fatigue test was conducted to evaluate the fatigue strengths of the Example, Comparative Example 1, and Comparative Example 2. The test apparatus was operated under load control with a sine wave waveform. In the test, the stress ratio was 0.1, the frequency was 10 Hz, and the distance between the chucks was 90 mm. The maximum number of cycles was set to one million.

### Test Results

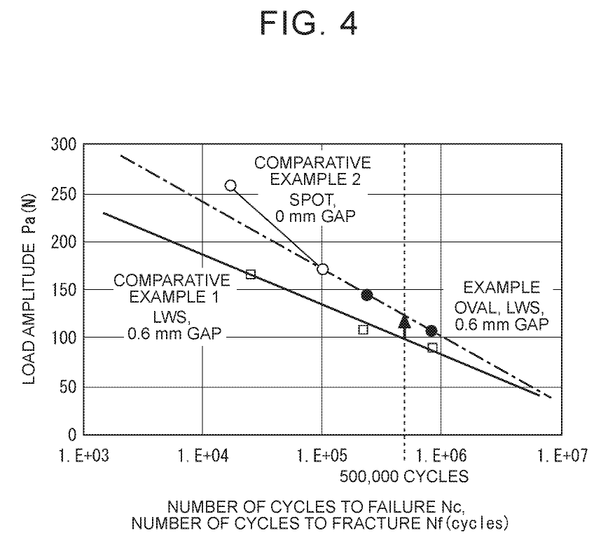

Next, the test results of the Example, Comparative Example 1, and Comparative Example 2 will be described with reference to FIG. 4. FIG. 4 is a graph showing the S-N curves of the Example, Comparative Example 1, and Comparative Example 2. In the S-N curves of FIG. 4, the horizontal axis represents the number of cycles to failure Nc or the number of cycles to fracture Nf, i.e., the number of cycles, and the vertical axis represents the load amplitude Pa. In the S-N curves of FIG. 4, the Example is indicated by black circles and a long dashed short dashed line, Comparative Example 1 by white squares and a thick continuous line, and Comparative Example 2 by white circles and a thin continuous line.

As shown in FIG. 4, at 500,000 cycles, the load amplitude of the Example having an oval weld is about 20% greater than that of Comparative Example 1 having a circular weld. Accordingly, even with the same laser welding, an oval weld provides greater fatigue strength than a circular weld.

As shown in FIG. 4, at 500,000 cycles, the load amplitude of the Example having an oval weld formed by laser welding is approximately the same as that of Comparative Example 2 welded by spot welding. Therefore, by forming the weld in an oval shape, sufficient fatigue strength can be ensured even with laser welding.

The present disclosure is not limited to the above embodiment, and can be modified as appropriate without departing from the spirit and scope of the present disclosure.

What is claimed is:

1. A laser welding method in which a plurality of metal plates stacked together is welded together by irradiating the metal plates with a laser beam, the laser welding method comprising:
irradiating the metal plates with the laser beam to form a molten pool; and
scanning the laser beam one or more times along a periphery of the molten pool to enlarge the molten pool,
wherein the molten pool is formed in an oval shape as viewed in plan.

2. The laser welding method according to claim 1, wherein:
the oval shape is a shape in which semicircles are connected by straight line portions, and
the straight line portions are longer than a radius of the semicircles.

3. The laser welding method according to claim 2, wherein the straight line portions have a length of at least 1 mm.

4. A joined assembly in which a plurality of metal plates stacked together is welded together by irradiating the metal plates with a laser beam, wherein a weld joining the metal plates has an oval shape as viewed in plan.

5. The joined assembly according to claim 4, wherein:
the oval shape is a shape in which semicircles are connected by straight line portions, and
the straight line portions are longer than a radius of the semicircles.
